(19) United States
(12) Patent Application Publication
(10) Pub. No.: US 2026/0068279 A1
(43) Pub. Date: Mar. 5, 2026

(54) EXTENDED DRAIN METAL OXIDE SEMICONDUCTOR DEVICE

(71) Applicant: GlobalFoundries Singapore Pte. Ltd., Singapore (SG)

(72) Inventors: Xin Chen, Singapore (SG); Fangyue Liu, Singapore (SG); Jiaxuan Kang, Singapore (SG); Wensheng Deng, Singapore (SG); Boon Guan Oon, Singapore (SG); Rui Tze Toh, Singapore (SG); Wong Kin Wei Jason, Singapore (SG); Yung Fu Chong, Singapore (SG); Dong Wang, Singapore (SG); Wee Kiat Tan, Singapore (SG)

(21) Appl. No.: 18/816,708

(22) Filed: Aug. 27, 2024

(51) Int. Cl. H01L 29/49; H01L 21/28; H01L 21/84; H01L 27/12; H01L 29/45; H01L 29/78

(52) U.S. Cl. CPC H10D 64/663; H10D 30/601; H10D 30/637; H10D 64/62; H10D 86/01; H10D 86/201

(57) ABSTRACT

The present disclosure relates to semiconductor structures and, more particularly, to an extended drain metal oxide semiconductor device and methods of manufacture. The structure includes: a gate structure including a gate dielectric material and a gate electrode with a stepped feature; sidewall spacers on sidewalls of the gate electrode, the sidewall spacers including a notched feature adjacent to the gate electrode; and a silicide contact on a surface of the gate electrode, the silicide contact being free of breaks on the surface of the gate electrode.

### BACKGROUND

The present disclosure relates to semiconductor structures and, more particularly, to an extended drain metal oxide semiconductor device and methods of manufacture.

An Extended Drain MOSFET (EDMOS) is a high voltage device used to implement modern power integrated circuits. The EDMOS may be used in amplifiers, including microwave power amplifiers, RF power amplifiers and audio power amplifiers.

### SUMMARY

In an aspect of the disclosure, a structure comprises: a gate structure comprising a gate dielectric material and a gate electrode with a stepped feature; sidewall spacers on sidewalls of the gate electrode, the sidewall spacers comprising a notched feature adjacent to the gate electrode; and a silicide contact on a surface of the gate electrode, the silicide contact being free of breaks on the surface of the gate electrode.

In an aspect of the disclosure, a structure comprises: an insulator layer over a semiconductor substrate; a raised epitaxial semiconductor material over the insulator layer, the raised epitaxial semiconductor material comprises a source region, a channel region and an extended drain region; shallow trench isolation structures adjacent to the raised epitaxial semiconductor material; a gate structure with a stepped feature extended over the raised epitaxial semiconductor material; sidewall spacer material on sidewalls of the gate electrode, the sidewall spacers having a varying width along a length of the gate structure; and a silicide contact over the gate structure.

In an aspect of the disclosure, a method comprises: forming a raised epitaxial semiconductor material over an insulator layer; forming shallow trench isolation structures adjacent to the raised epitaxial semiconductor material; forming a gate structure over the raised epitaxial semiconductor material; forming sidewall spacers with a varying width on sidewalls of the gate structure; and forming a silicide contact over the gate structure which is free of silicide breakage.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1A shows a first cross-sectional view of a device in accordance with aspects of the present disclosure.

FIG. 1B shows a second cross-sectional view of a device in accordance with aspects of the present disclosure.

FIG. 2 shows a representation of a gate structure using a scanning electron microscope.

FIG. 3 shows a representation of a gate structure with residual spacer material using a scanning electron microscope.

FIGS. 4A-4D show intermediate fabrication steps in accordance with aspects of the present disclosure.

### DETAILED DESCRIPTION

The present disclosure relates to semiconductor structures and, more particularly, to an extended drain metal oxide semiconductor device and methods of manufacture. More specifically, the present disclosure relates to an extended drain metal oxide semiconductor (EDMOS) device with a polysilicon gate structure. In embodiments, the polysilicon gate structure includes a stepped feature which is devoid of any residual spacer material. Advantageously, the processes for manufacturing the EDMOS device provides process variation improvements, e.g., Fmax variation improvement. For example, by removing residual spacer material on top of the polysilicon gate, it is now possible to improve Fmax variation that would otherwise be caused by silicide breakage.

In conventional EDMOS devices, sidewall spacers are provided on sidewalls of the gate structure and, more particularly, on sidewalls of a polysilicon material of the gate structure. To form the sidewall spacers, an oxide and/or nitride material may be blanket deposited over the gate structure (and other structures on the semiconductor substrate), followed by an etching process. The etching process will remove the sidewall spacer material on lateral surfaces of the device, e.g., on a top surface of the gate structure and exposed surfaces of the semiconductor substrate, leaving the sidewall spacer material on the sidewalls of the polysilicon material. Due to process limitations on the etching process, though, residual spacer material, e.g., nitride and/or oxide, may remain on the surface of the gate structure, in addition to at an interface with a shallow trench isolation structure. This residual material will prevent silicide from forming uniformly on a surface of the polysilicon material resulting in a silicide break on the polysilicon material. This silicide break, in turn, affects the device performance. In contrast, the processes of the present disclosure include an additional masking/etching step to remove residual spacer material from the top surface of the polysilicon material. In this way, there will be no silicide breakage on the polysilicon material or an interface of a shallow trench isolation structure. Accordingly, process variations and device performance can be improved.

The device of the present disclosure can be manufactured in a number of ways using a number of different tools. In general, though, the methodologies and tools are used to form structures with dimensions in the micrometer and nanometer scale. The methodologies, i.e., technologies, employed to manufacture the device of the present disclosure have been adopted from integrated circuit (IC) technology. For example, the structures are built on wafers and are realized in films of material patterned by photolithographic processes on the top of a wafer. In particular, the fabrication of the device uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

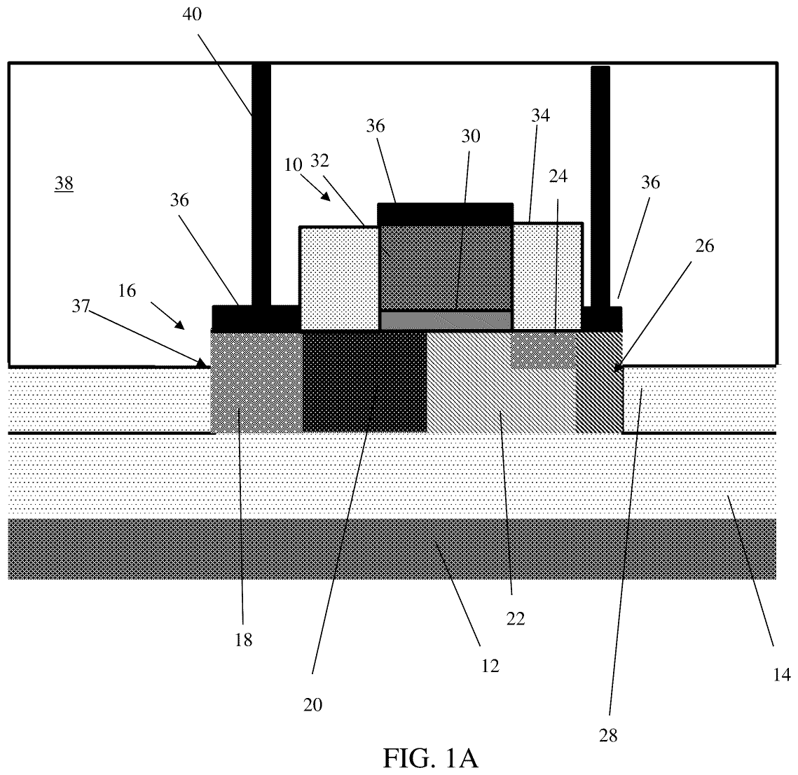

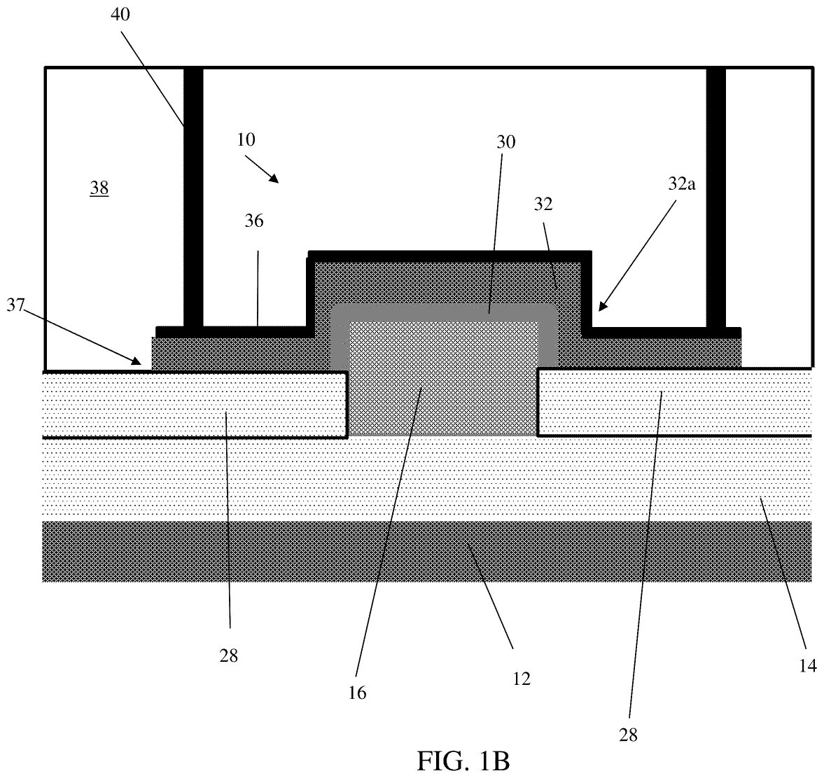

FIGS. 1A and 1B show different cross-sectional views of a device in accordance with aspects of the present disclosure. In particular, FIG. 1A shows a cross-sectional view of an EDMOS device along a gate length direction; whereas FIG. 1B shows a cross-section view of the EDMOS device along a gate width direction. As shown in each of the cross-sectional views, the gate structure 10 and, more particularly, polysilicon material forming the gate structure is devoid of any spacer material residue. This allows silicide formation along an entire top surface of the polysilicon material without any silicide breakage.

The device shown in FIGS. 1A and 1B includes a semiconductor substrate 12. The semiconductor substrate 12 may be composed of any suitable material including, but not limited to, Si, SiGe, SiGeC, SiC, GaAs, InAs, InP, and other III/V or II/VI compound semiconductors. The semiconductor substrate 12 may comprise any suitable crystallographic orientation (e.g., a (100), (110), (111), or (001) crystallographic orientation).

A buried insulator layer 14, e.g., buried oxide layer (BOX), may be formed over the semiconductor substrate 12. The buried insulator layer 14 may include a dielectric material such as silicon dioxide, silicon nitride, silicon oxynitride, boron nitride or a combination thereof. The buried insulator layer 14 may be formed by any suitable process, such as separation by implantation of oxygen (SIMOX), oxidation, deposition, and/or other suitable process. For example, the buried insulator layer 14 may be formed by chemical vapor deposition (CVD), plasma enhanced chemical vapor deposition CVD (PECVD) or physical vapor deposition (PVD). In further embodiments, the buried insulator layer 14 may be formed using a thermal growth process, such as thermal oxidation or by implanting oxygen atoms into a bulk semiconductor substrate and thereafter annealing the structure.

A top semiconductor layer 16 may be provided on the buried insulator layer 14. In embodiments, the top semiconductor layer 16 may be the same semiconductor material as the semiconductor substrate 14, e.g., single crystalline semiconductor material, such as, for example, single crystalline silicon. The top semiconductor layer 16 can be formed by a deposition process, such as CVD or PECVD. Alternatively, the top semiconductor layer 16 may be formed using a smart cut process where two semiconductor wafers are bonded together with an insulator in between.

In embodiments, the top semiconductor layer 16 may further comprise epitaxially grown semiconductor material, e.g., to form a raised region. The raised region may, for example, be used to form the gate structure 10, e.g., including the source region, drain region, channel region and gate electrode. This raised region will have an upper surface above the buried insulator layer.

Examples of various epitaxial growth process apparatuses that can be employed in the present disclosure include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The epitaxial growth may be performed at a temperature of from 300° C. to 800° C. The epitaxial growth can be performed utilizing any well-known precursor gas or gas mixture. Carrier gases like hydrogen, nitrogen, helium and argon can be used.

In embodiments, the top semiconductor layer 16 (with epitaxial semiconductor material) may be subjected to ion implantation processes to form the implanted regions 18, 20, 22, 24, 26. In embodiments, implanted regions 18, 20, 22, 24, 26 may form the source region, drain region and channel region of the gate structure 10 (all of which are raised above other features of the structure). By way of example, the implanted regions include, e.g., N+ region 18, an extended drain region comprising N-type dopant 20 (e.g., drift region), a P− region 22, a shallow N+ region 24 and a P+ region 26.

The implanted regions 18, 20, 22, 24, 26 may be formed by introducing a concentration of a different dopant of different conductivity types in the top semiconductor layer 16. For example, to form the implanted regions 18, 20, 22, 24, 26 respective patterned implantation masks may be used to define selected areas exposed for the implantations. The implantation mask used to select the exposed area for forming N− regions is stripped after implantation, and before the implantation mask used to form P− regions (or vice versa). The implantation masks may include a layer of a light-sensitive material, such as an organic photoresist, applied by a spin coating process, pre-baked, exposed to light projected through a photomask, baked after exposure, and developed with a chemical developer. Each of the implantation masks has a thickness and stopping power sufficient to block masked areas against receiving a dose of the implanted ions. The P-type regions are doped with p-type dopants, e.g., Boron (B), and the N-type regions are doped with n-type dopants, e.g., Arsenic (As), Phosphorus (P) and Antimony (Sb), among other suitable examples. An annealing process may be performed to drive in the dopants into the top semiconductor layer 16. The annealing process may accordingly provide the drain region and the source region deeper into the top semiconductor layer 16.

Shallow trench isolation structures 28 may be formed adjacent to the implanted regions which form the source region, drain (e.g., extended drain region) and channel region of the gate structure 10. The shallow trench isolation structures 28 may be formed in the top semiconductor layer 16, extending to the buried insulator layer 14. In this way, the implanted regions may be physically and electrically isolated from remaining portions of the structure. In embodiments, the shallow trench isolation structures 28 will be lower than the raised region described herein, e.g., the gate structure 10 including the source region, the drain region and the channel region.

The shallow trench isolation structures 28 can be formed by conventional lithography, etching and deposition methods known to those of skill in the art. By way of example, a resist formed over the top semiconductor layer 16 is exposed to energy (light) and developed utilizing a conventional resist developer to form a pattern (opening). An etching process with a selective chemistry, e.g., reactive ion etching (RIE), will be used to transfer the pattern from the patterned photoresist layer to top semiconductor layer 16 to form one or more trenches in the top semiconductor layer 16 through the openings of the resist. Following the resist removal by a conventional oxygen ashing process or other known stripants, the insulator material, e.g., oxide material, can be deposited by any conventional deposition processes, e.g., chemical vapor deposition (CVD) processes. Any residual material on the surface of the top semiconductor layer 16 can be removed by conventional chemical mechanical polishing (CMP) processes.

The gate structure 10 may comprise, for example, a gate dielectric material 30 and a gate electrode 32 formed on the raised, top semiconductor layer 16 and, more specifically, over the epitaxial semiconductor layer which forms an upper portion of the raised, top semiconductor layer 16. In embodiments, the gate dielectric material 30 may be a high-k gate dielectric material, e.g., hafnium base material such as hafnium oxide, amongst other known gate dielectric materials. The gate electrode 32 may be polysilicon material. The gate dielectric material 30 may be deposited by a conventional deposition method such as, e.g., atomic layer deposition (ALD), PECVD, etc. The polysilicon material 32 may be deposited by a conventional deposition method, e.g., CVD. In embodiments, the gate dielectric material 30 and the gate electrode 32 may be patterned using conventional RIE process.

As shown in FIG. 1B, the gate electrode 32 includes a stepped feature 32a, which extends at a junction between the raised, top semiconductor layer 16 and the shallow trench isolation structures 28. More specifically, the stepped feature 32a is provided at a vertical surface of the epitaxial material of the raised, top semiconductor layer 16 and a lateral surface of the shallow trench isolation the structures 28. The stepped feature 32a may an interior corner at the junction between the surfaces of the gate electrode 32 and the shallow trench isolation structures 28, e.g., at an interface of the vertical surface of the raised, top semiconductor layer 16 and the lateral, lower surface of the shallow trench isolation the structures 28.

Referring back to FIG. 1A, sidewalls spacers 34 are formed on the patterned gate structure 10 and, more specifically, on sidewalls of the polysilicon material 32. In embodiments, the sidewall spacers 34 may be an oxide material, nitride material or combination thereof. The sidewalls spacers 34 are formed by a blanket deposition process, e.g., CVD, followed by an anisotropic etching process. In embodiments, the sidewalls spacers 34 may have a varying width or height along its length, may be asymmetric with the sidewall spacer 34 covering the drift region 20 larger than on a source side of the gate structure 10, and/or may be narrower adjacent to an edge of the interface with the active region and shallow trench isolation structure 28, as examples.

As should be understood by those of skill in the art, the sidewall spacers 34 may be patterned using an anisotropic etching process which includes a lateral etching component. In embodiments, the etchant can be a dry plasma etching process using, for example, fluorocarbon (CF) gases as an example, although other etching processes are contemplated herein. In embodiments, this etching process leaves residual spacer material at the corner (e.g., stepped feature) 32a of the polysilicon material 32, in addition to the corner 37 of the raised region and the shallow trench isolation structures 28.

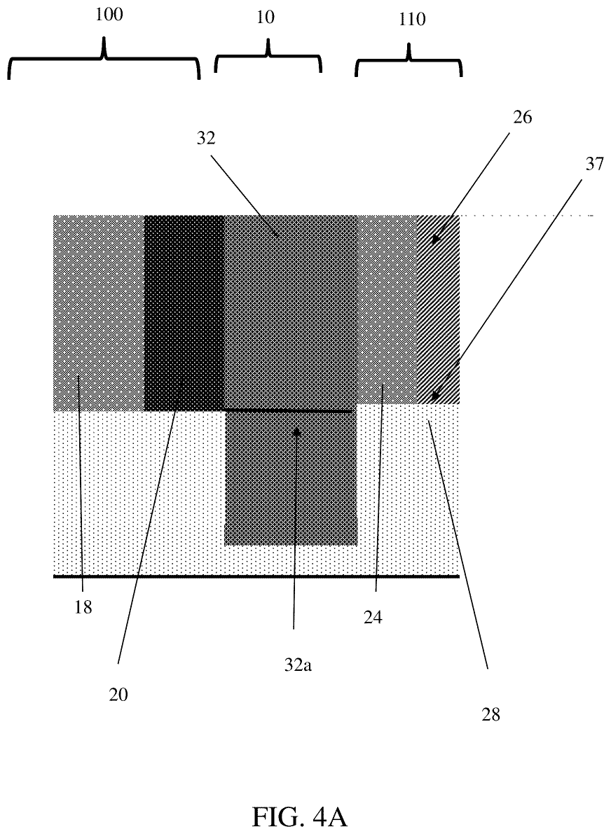

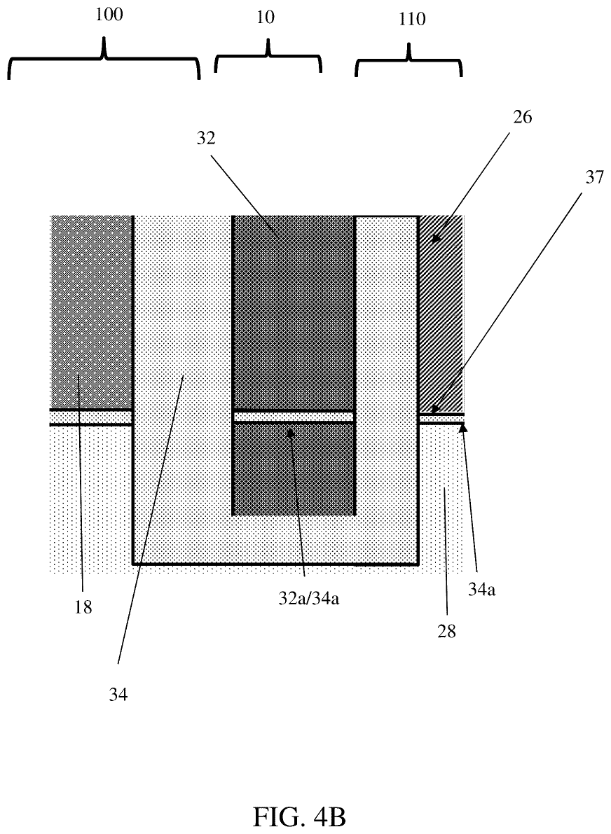

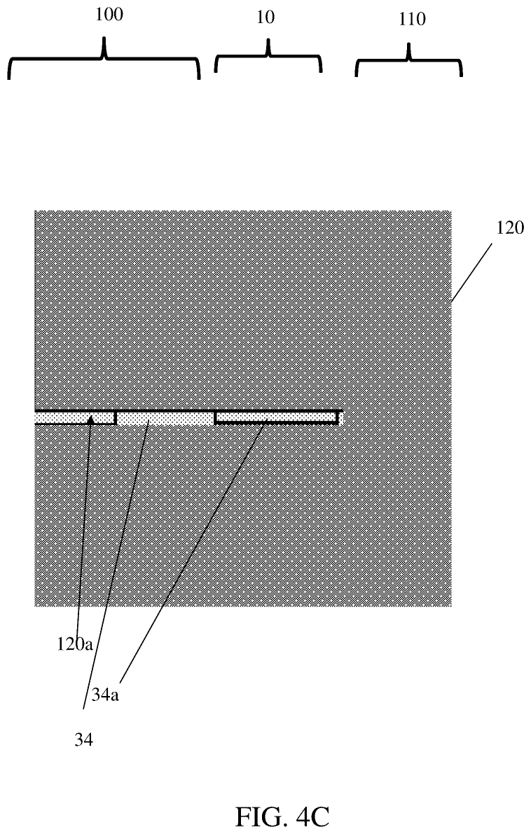

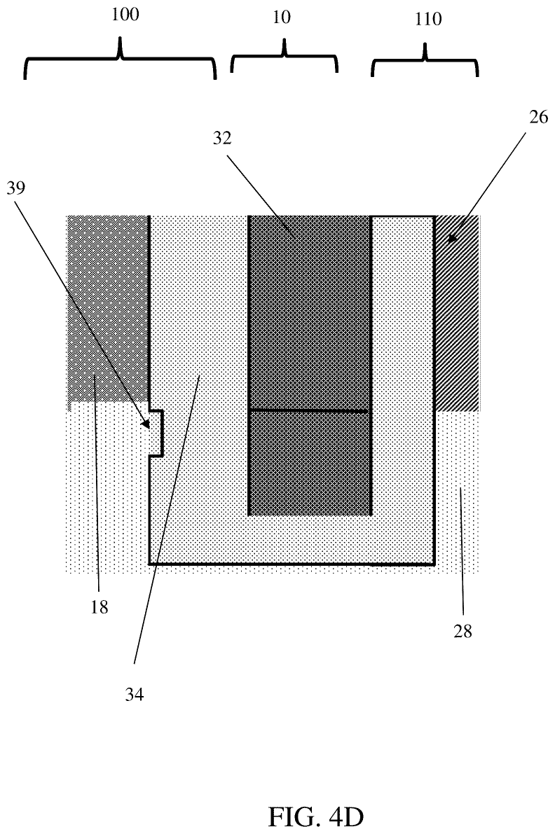

To remove this excessive spacer material, an additional lithography and etching process is performed. For example, a block material, e.g., resist material, is deposited and patterned to form an opening exposing the residual spacer material at the corner 32a of the polysilicon material 32 (see, e.g., FIG. 4C). An additional etching process is performed to remove the residual spacer material at the corner 32a of the polysilicon material 32 in addition to the corner 37a between the active region, e.g., raised region and the shallow trench isolation structures 28.

In embodiments, the additional etching process, e.g., RIE, may be a wet or dry etching process. For example, in embodiments, a hydrogen fluoride (HF) etchant or other conventional wet or dry etchants may be used to remove the residual oxide and/or nitride materials. The resist material is removed using conventional oxygen ashing or other conventional stripants, followed by a cleaning process known to those of skill in the art. For example, the cleaning process may be dilute hydrofluoric acid and HFEG (HF diluted by ethylene glycol). In this way, the polysilicon material 32 is completely free of the residual spacer material.

In embodiments, the removal of the residual spacer material may result in the sidewalls spacers 34 having a varying width or height along its length. For example, as shown in FIG. 4D, the sidewall spacers 34 may be selectively thinned by conventional lithography and etching processes as described already herein which will form a notch 39 along a sidewall of the gate structure 10. In this way, the sidewall spacers 34 may be asymmetrical along a length of the gate structure 10, e.g., may have a varying width along the length of the gate structure 10. For example, the sidewall spacer 34 may be narrower adjacent to the edge or corner 37a of the active region (e.g., raised region) and shallow trench isolation structures, which is due to the removal of the residual spacer material.

A silicide contact 36 may be formed over the surface of polysilicon material 32 of the gate structure 10, in addition to the source and drain regions, e.g., implanted regions 18, 26. As should be understood by those of skill in the art, the silicide process begins with deposition of a thin transition metal layer, e.g., nickel, cobalt or titanium, over the exposed semiconductor material. After deposition of the material, the structure is heated allowing the transition metal to react with exposed silicon (or other semiconductor material as described herein) in the active regions of the semiconductor device (e.g., source, drain, gate contact region (e.g., gate electrode) forming a low-resistance transition metal silicide. Following the reaction, any remaining transition metal is removed by chemical etching, leaving silicide contacts 36 in the active regions of the device. As there is no residual spacer material at the corner 32a, it is now possible to form the silicide contacts 36 without any silicide breaks.

As further shown in FIGS. 1A and 1B, contacts 40 may be formed in contact with the silicide contacts 36. In embodiments, the contacts 40 are formed in interlevel dielectric material 38. In embodiments, the interlevel dielectric material 38 may be layers of oxide and/or nitride. The contacts 40 may be any conventional metal or metal alloy material. For example, the contacts 40 may be tungsten, aluminum or copper as examples. The contacts may also include a liner material of, for example, TiN and/or TaN. The interlevel dielectric material 38 may be deposited using a conventional deposition process, e.g., CVD. The contacts 40 may be formed by conventional lithography, etching (RIE) and deposition processes as is known in the art such that no further explanation is required for a complete understanding of the present disclosure. A chemical mechanical polishing (CMP) process may be used to remove any residual material from a top surface of the interlevel dielectric material 38.

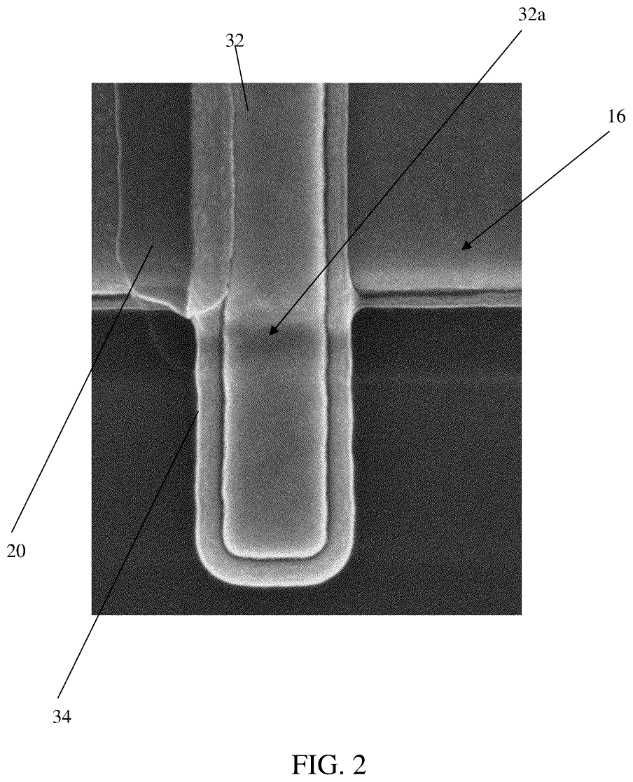

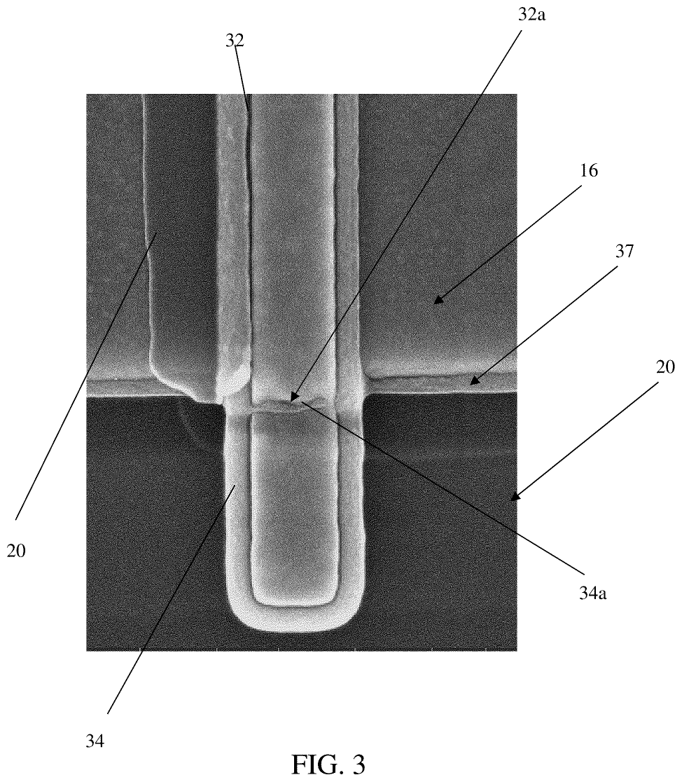

FIG. 2 shows a representation of a gate structure using a scanning electron microscope (SEM). As shown in FIG. 2, the corner (e.g., stepped feature) 32a of the polysilicon material is devoid of any residual spacer material. In this way, the silicide contacts can be formed without any breaks. FIG. 3, in comparison, shows residual spacer material 34a at the corner (e.g., stepped feature) 32a of the polysilicon material 32, prior to removal of such material in accordance with aspects of the present disclosure.

FIGS. 4A-4D show intermediate fabrication steps in accordance with aspects of the present disclosure. FIG. 4A shows the formation of the gate structure 10 with the drain region 100 (including the drift region 20 and implant region 18) and source region 110 (including the implant regions 24, 26) on opposing sides of the gate structure 10. The fabrication processes of forming the gate structure 10 with the drain region 100 (including drift region 20) and source region 110 are described with respect to FIGS. 1A and 1B.

FIG. 4B shows the formation of the sidewall spacers 34 (including a spacer partially over drain region 100 and more particularly over the drift region 20). In this representation, the residual spacer material 34a remains on the polysilicon material 32 at the stepped feature 32a and at the interface 37 of the shallow trench isolation structure 28 and the raised region, e.g., top of the semiconductor layer 16. after the spacer formation.

FIG. 4C, on the other hand, shows a mask 120 over the structures, which includes a patterned opening 120a to expose the residual spacer material 34a on the stepped features 32a and the interface 37 between the raised semiconductor material and the shallow trench isolation structure. The fabrication processes continue with an etching process to remove the residual spacer material 34a as described herein. The mask 120 can be removed after the etching process, followed by a cleaning process and contact formation, e.g., back end of the line (BEOL) processes described with respect to FIGS. 1A and 1B.

FIG. 4D shows the structure after the removal of the residual spacer material 34. As shown in this representation, the etching process will remove the residual spacer material 34 as described herein, in addition to thinning the sidewall spacers 34 to form a notch 39 along a sidewall of the gate structure 10. In this way, the sidewall spacers 34 may be asymmetrical along a length of the gate structure 10, e.g., may have a varying width along the length of the gate structure 10. For example, the sidewall spacer 34 may be narrower (e.g., notch 39) adjacent to the edge or corner 37a of the active region (e.g., raised region) and shallow trench isolation structures 28, which is due to the removal of the residual spacer material. Also, in embodiments, the sidewalls spacer 34 may also have a different height, e.g., lower, at such locations due to the additional etching processes.

The device can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a gate structure comprising a gate dielectric material and a gate electrode with a stepped feature;
sidewall spacers on sidewalls of the gate electrode, the sidewall spacers comprising a notched feature adjacent to the gate electrode; and
a silicide contact on a surface of the gate electrode, the silicide contact being free of breaks on the surface of the gate electrode.

2. The structure of claim 1, wherein the gate structure is located on a raised semiconductor material with a source region, a drain region and a channel region.

3. The structure of claim 2, wherein the raised semiconductor material is in relation to an underlying insulator material sitting on a semiconductor substrate.

4. The structure of claim 2, wherein the raised semiconductor material is in relation to shallow trench isolation structures adjacent to the gate structure.

5. The structure of claim 2, wherein the raised semiconductor material comprises epitaxial semiconductor material.

6. The structure of claim 1, wherein the notched feature is a thinned portion at an interface at the gate structure and a shallow trench isolation structure.

7. The structure of claim 1, wherein the gate electrode is free of residue sidewall spacer material.

8. The structure of claim 1, wherein the sidewall spacers comprise a varying height along a length of the gate structure.

9. The structure of claim 1, wherein the stepped feature of the gate electrode is provided at an interface between a vertical surface of epitaxial semiconductor material and a lateral surface of shallow trench isolation structures.

10. The structure of claim 2, wherein the drain region comprises an extended drain region which is covered by the sidewall spacers.

11. The structure of claim 1, wherein the silicide contact covers the stepped feature devoid of any silicide breakage.

12. A structure comprising:
an insulator layer over a semiconductor substrate;
a raised epitaxial semiconductor material over the insulator layer, the raised epitaxial semiconductor material comprises a source region, a channel region and an extended drain region;
shallow trench isolation structures adjacent to the raised epitaxial semiconductor material;
a gate structure with a stepped feature extended over the raised epitaxial semiconductor material;
sidewall spacer material on sidewalls of the gate electrode, the sidewall spacers having a varying width along a length of the gate structure; and
a silicide contact over the gate structure.

13. The structure of claim 12, wherein the sidewall spacer material comprises a notch.

14. The structure of claim 13, wherein the notch is adjacent to the stepped feature.

15. The structure of claim 12, wherein the sidewall spacer material comprises a varying height along a length of the gate structure.

16. The structure of claim 12, wherein the gate structure comprises a gate electrode free of residual spacer sidewall spacer material at the stepped feature.

17. The structure of claim 12, wherein the stepped feature is along a vertical sidewall of the raised epitaxial semiconductor material and a lateral surface of the shallow trench isolation structures.

18. A method comprising:
forming a raised epitaxial semiconductor material over an insulator layer;
forming shallow trench isolation structures adjacent to the raised epitaxial semiconductor material;
forming a gate structure over the raised epitaxial semiconductor material;
forming sidewall spacers with a varying width on sidewalls of the gate structure; and
forming a silicide contact over the gate structure which is free of silicide breakage.

19. The method of claim 18, wherein the forming sidewall spacers with a varying width comprises forming a patterned mask to expose residual sidewall spacer material while blocking remaining portions of the gate structure.

20. The method of claim 18, wherein the forming of the sidewall spacers comprises forming the sidewall spacers with a varying height.
